(19) United States
(12) Patent Application Publication
(10) Pub. No.: US 2025/0098191 A1
(43) Pub. Date: Mar. 20, 2025

(54) MANUFACTURING METHOD OF SEMICONDUCTOR DEVICE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kazusa ARIMA, Komatsu Ishikawa (JP)

(21) Appl. No.: 18/598,456

(22) Filed: Mar. 7, 2024

(30) Foreign Application Priority Data
Sep. 15, 2023 (JP) 2023-150438

(51) Int. Cl. H01L 29/739; H01L 21/8234; H01L 29/66; H01L 29/78

(52) U.S. Cl. CPC H10D 12/441; H10D 12/032; H10D 30/025; H10D 30/63; H10D 84/0149; H10D 84/038

(57) ABSTRACT

A manufacturing method a semiconductor device according to an embodiment is a manufacturing method a semiconductor device located on a semiconductor wafer within a region surrounded by a first dicing line extending in a first direction and a second dicing line perpendicular to the first direction, the semiconductor device including a cell region and a termination region, the cell region including a semiconductor device located within a semiconductor substrate, the termination region including a metal wiring line located on the semiconductor substrate and electrically connected to the semiconductor device. In this method, a stopper film is formed around the metal wiring line in the termination region, a protection film covering the metal wiring line and ending at a side surface of the stopper film is formed, and the semiconductor wafer is diced along the first dicing line and the second dicing line.

### CROSS-REFERENCE TO RELATED APPLICATIONS

This application is based upon and claims the benefit of priority from Japanese Patent Application No. 2023-150438, filed on Sep. 15, 2023; the entire contents of which are incorporated herein by reference.

### FIELD

Embodiments of the present invention relate to a manufacturing method of a semiconductor device and a semiconductor device.

### BACKGROUND

A vertical semiconductor device having a cell region and a termination region is known as an example of a semiconductor device. A power semiconductor device such as an IGBT (Insulated Gate Bipolar Transistor) or a MOSFET (Metal Oxide Semiconductor Field Effect Transistor) is located in the cell region.

Meanwhile, a metal wiring line electrically connected to the above-mentioned power semiconductor device is located in the termination region. The metal wiring line is covered with a protection film. One of steps to produce the protection film is a development step, in which an end portion of the protection film is sometimes formed into a tapered shape on a dicing line. In this case, in order to secure the coverage of the metal wiring line, it is necessary to design a dicing line width with an allowance. Additionally, it is difficult to secure the uniformity of an end portion shape of the protection film within a wafer, which makes the dicing line width likely to vary.

### BRIEF DESCRIPTION OF THE DRAWINGS

FIG. 1 is a plan view of a semiconductor device according to a first embodiment;

FIG. 2 is a cross sectional view along a cut line A-A in FIG. 1;

FIG. 3 is a cross sectional view along a cut line B-B in FIG. 1;

FIG. 4 is a cross sectional view illustrating a film formation step of an oxide film;

FIG. 5 is a cross sectional view illustrating a lithography step;

FIG. 6 is a cross sectional view illustrating an etching step;

FIG. 7 is a cross sectional view illustrating a removal step of a photoresist;

FIG. 8 is a cross sectional view illustrating a film formation step of a protection film;

FIG. 9 is a cross sectional view of a termination region of a semiconductor device according to a comparative example;

FIG. 10 is a cross sectional view of the termination region of the semiconductor device according to the comparative example; and

FIG. 11 is a plan view of a semiconductor device according to a second embodiment.

### DETAILED DESCRIPTION

Embodiments will now be explained with reference to the accompanying drawings. The present invention is not limited to the embodiments.

A manufacturing method of a semiconductor device according to an embodiment is a manufacturing method of a semiconductor device located on a semiconductor wafer within a region surrounded by a first dicing line extending in a first direction and a second dicing line perpendicular to the first direction, the semiconductor device including a cell region and a termination region, the cell region including a semiconductor device located within a semiconductor substrate, the termination region including a metal wiring line located on the semiconductor substrate and electrically connected to the semiconductor device. The method includes: forming a stopper film around the metal wiring line in the termination region; forming a protection film, the protection film covering the metal wiring line and ending at a side surface of the stopper film; and dicing the semiconductor wafer along the first dicing line and the second dicing line.

### First Embodiment

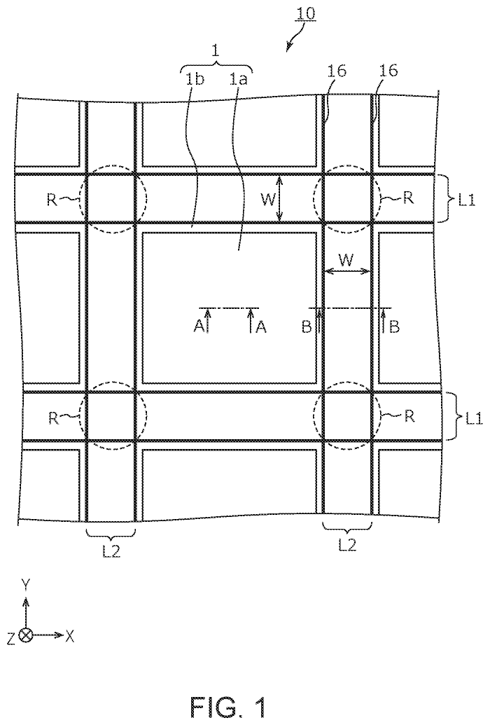

FIG. 1 is a plan view of a semiconductor device 1 according to a first embodiment. The semiconductor device 1 illustrated in FIG. 1 is in a state of not being diced from a semiconductor wafer 10. Hereinafter, the locations and configurations of components of the semiconductor device are sometimes described with use of an X-axis, a Y-axis, and a Z-axis in the drawings. The X-axis, Y-axis, and Z-axis, which are perpendicular to one another, represent an X-direction, a Y-direction, and Z-direction, respectively. Additionally, description is sometimes made with the assumption that the Z-direction is an upside and the direction opposite thereto is a downside. In the present embodiment, the X-direction and the Y-direction, which correspond to a first direction and a second direction, respectively, represent in-plane directions parallel with a front surface (or a back surface) of the semiconductor device 1. The Z-direction, which corresponds to a third direction, represents an out-of-plane direction perpendicular to the front surface (or the back surface) of the semiconductor device 1.

Additionally, signs p, p⁺ mean that p-type impurity concentrations are increased in this order. Further, signs n⁻, n, n⁺ mean that an n-type impurity concentration becomes higher in this order.

The impurity concentration is measurable by, for example, SIMS (Secondary Ion Mass Spectrometry). Additionally, a relative level of the impurity concentration is determinable from, for example, a level of a carrier concentration obtained by SCM (Scanning Capacitance Microscopy). Additionally, a distance such as a depth of the semiconductor region is obtainable by, for example, SIMS.

As illustrated in FIG. 1, the semiconductor wafer 10 includes a plurality of semiconductor devicees 1 arranged in rows and columns along the X-direction and the Y-direction. A first dicing line L1 is located between ones of the semiconductor devicees 1 opposed to each other in the Y-direction and the first dicing line L1 extends in the X-direction. Additionally, a second dicing line L2 is located between ones of the semiconductor devicees 1 opposed to each other in the X-direction and the second dicing line L2 extends in the Y-direction. In other words, the semiconductor devicees 1 are located on the semiconductor wafer 10 within regions surrounded by the first dicing lines L1 and the second dicing lines L2. It should be noted that a width of the first dicing line L1 and a width of the second dicing line L2 are the same in the present embodiment but may be different.

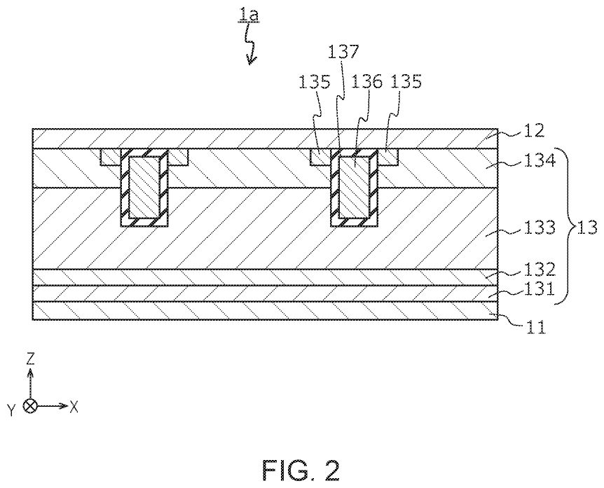

Each of the semiconductor devicees 1 includes a cell region 1a and a termination region 1b located around the cell region 1a. Here, description is made on a structure of the cell region 1a with reference to FIG. 2.

FIG. 2 is a cross sectional view along a cut line A-A in FIG. 1. The cell region 1a includes a first electrode 11, a second electrode 12, and a semiconductor substrate 13 as illustrated in FIG. 2. Here, description is made on a case where the semiconductor device located in the cell region 1a includes an IGBT. The structure of the cell region 1a is, however, not limited to the structure illustrated in FIG. 2. The semiconductor device located in the cell region 1a may include, for example, a MOSFET.

The first electrode 11 is located on a back surface of the semiconductor substrate 13. The first electrode 11 can be formed by using, for example, a metal such as aluminum. The first electrode 11 functions as a collector electrode.

The second electrode 12 is opposed to the first electrode 11 in the Z-direction with the semiconductor substrate 13 in between. The second electrode 12 can be formed by using, for example, a metal such as aluminum. The second electrode 12 functions as an emitter electrode.

The semiconductor substrate 13 includes a p⁺ collector layer 131, an n⁺ buffer layer 132, an n base layer 133, a p base layer 134, an n⁺ emitter region 135, a gate electrode 136, and a gate insulation film 137.

The p⁺ collector layer 131 is located on the first electrode 11. The n⁺ buffer layer 132 is located on the p⁺ collector layer 131. The n base layer 133 is located on the n⁺ buffer layer 132.

The p base layer 134 is located on the n-base layer 133. The n⁺ emitter region 135 is in contact with the p base layer 134. The n⁺ emitter region 135 is in contact with the second electrode 12. An n-channel is formed in the p base layer 134 in response to a voltage between the gate electrode 136 and the second electrode 12 (the emitter electrode) becoming a threshold voltage or more. This causes a current path to be generated in the cell region 1a and the current path leads from the p⁺ collector layer 131 to the n⁺ emitter region 135 through the n-channel.

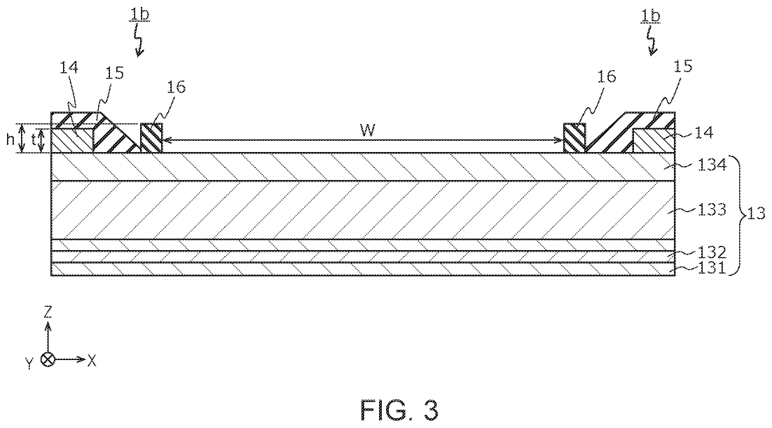

The gate electrode 136 is opposed to the p base layer 134 and the n⁺ emitter region 135 with the gate insulation film 137 in between. The gate electrode 136 can be formed by using, for example, polysilicon. Additionally, the gate insulation film 137 is, for example, a silicon oxide (SiO₂) film. Subsequently, description is made on a structure of the termination region 1b with use of FIG. 3.

FIG. 3 is a cross sectional view along a cut line B-B in FIG. 1. The termination region 1b includes the semiconductor substrate 13, a metal wiring line 14, a protection film 15, and a stopper film 16 as illustrated in FIG. 3.

A structure of the semiconductor substrate 13 is similar to that in the cell region 1a and a detailed description thereof is omitted, accordingly. Incidentally, none of the n⁺ emitter region 135, the gate electrode 136, and the gate insulation film 137 is located in the termination region 1b.

The metal wiring line 14 is located on an upper surface of the semiconductor substrate 13. The metal wiring line 14 is electrically connected to, for example, the second electrode 12 of the cell region 1a. A material of the metal wiring line 14 is, for example, aluminum (Al), an alloy of aluminum and copper (AlCu), or an alloy of aluminum and silicon (AlSi).

The protection film 15 covers the metal wiring line 14. The protection film 15 includes a resin film such as a polyimide film. In forming the protection film 15, a stretch of the protection film 15 from the termination region 1b to a dicing line of the semiconductor wafer 10 causes a dicing line width W to vary. Accordingly, in the present embodiment, the stopper film 16 is located in an outermost peripheral portion of the termination region 1b so as to prevent the protection film 15 from stretching. This causes distances between the stopper films 16 opposed to each other in the X-direction and the Y-direction to be the dicing line width W.

The stopper film 16 may be an electrically conductive film including aluminum, copper, or the like or may be an insulation film including silicon oxide (SiO₂), silicon nitride (SiN), or the like. Additionally, in order to more reliably prevent the protection film 15 from stretching, it is desirable that a height h of the stopper film 16 be greater than a thickness t of the metal wiring line 14.

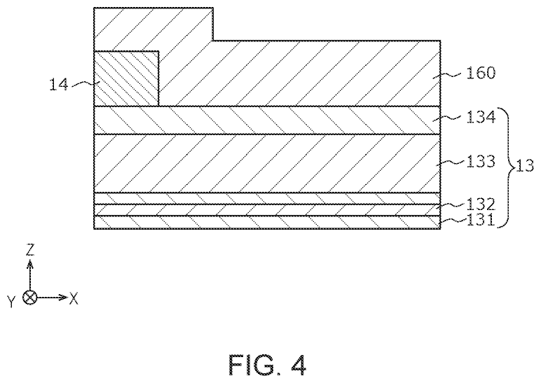

Here, description is made on a manufacturing method of the semiconductor device 1 according to the present embodiment with reference to FIG. 4 to FIG. 8. Here, a manufacturing method of a termination region 1b of the semiconductor device 1 is described. It should be noted that the cell region 1a can be formed by a usually utilized production method before the formation of the termination region 1b and a detailed description thereof is omitted, accordingly.

First, an oxide film 160 is formed to cover the upper surface of the semiconductor substrate 13 and a front surface of the metal wiring line 14 as illustrated in FIG. 4. The oxide film 160 is formed by, for example, CVD (Chemical Vapor Deposition). It should be noted that a nitride film or an electrically conductive film may be formed in place of the oxide film 160.

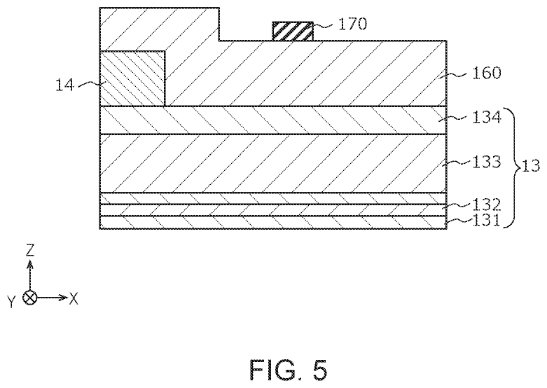

Next, a photoresist 170 is patterned on the oxide film 160 by lithography as illustrated in FIG. 5. In the present embodiment, the photoresist 170 is applied to, within the oxide film 160, a portion that is to be left as the stopper film 16.

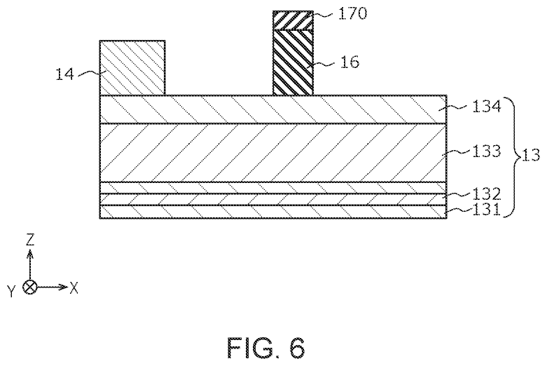

Next, the oxide film 160 is etched using the photoresist 170 as a mask as illustrated in FIG. 6. The oxide film 160 is etched by, for example, RIE (Reactive Ion Etching).

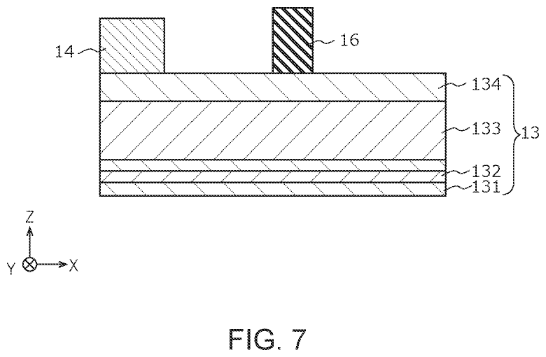

Next, the photoresist 170 is removed as illustrated in FIG. 7. This causes the stopper film 16 to be formed around the metal wiring line 14. It should be noted that the stopper film 16 can also be formed by performing the steps illustrated in FIG. 4 to FIG. 7 for a plurality of times to stack and accumulate the oxide films 160.

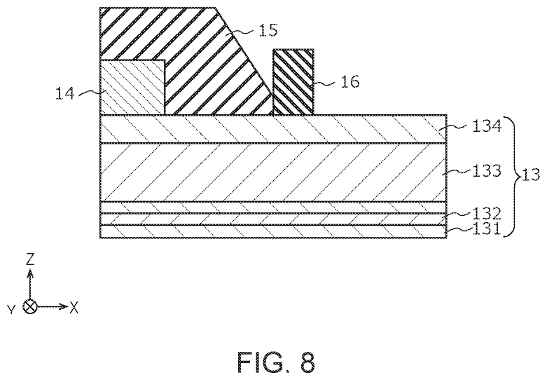

Lastly, the protection film 15 is formed to cover the metal wiring line 14, the protection film 15 ending at a side surface of the stopper film 16 opposed to the metal wiring line 14 as illustrated in FIG. 8. The protection film 15 can be formed by usually utilized production steps such as an exposure step and a development step. The termination region 1b is thus completed. After that, the semiconductor wafer 10 is diced in a grid pattern along the first dicing lines L1 and the second dicing lines L2 using a blade. The plurality of semiconductor devicees 1 (semiconductor chips) are thus singulated from the semiconductor wafer 10.

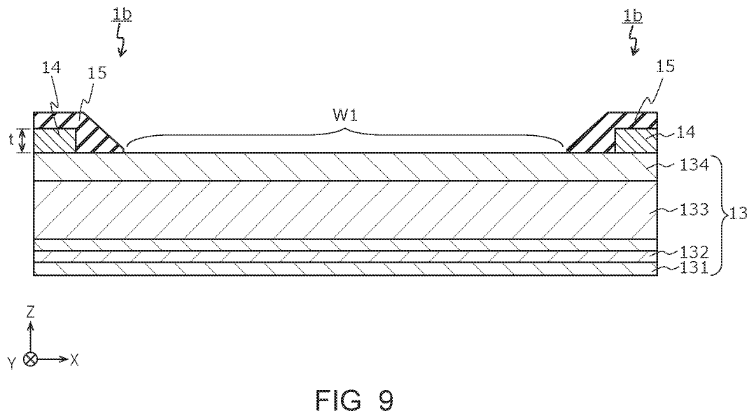

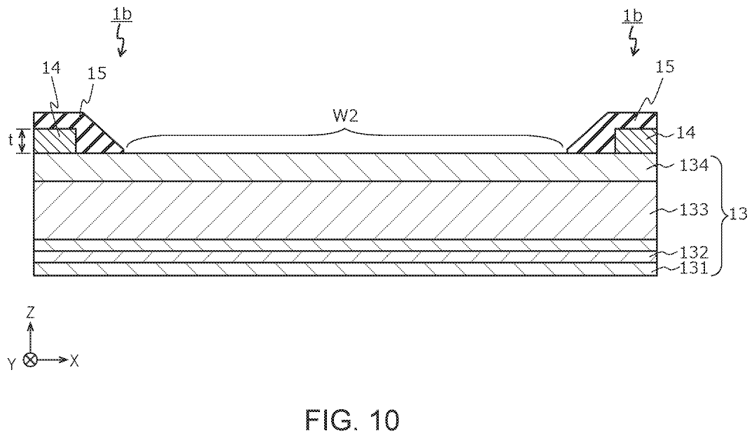

Here, description is made on a comparative example to be compared with the present embodiment with reference to FIG. 9 and FIG. 10.

FIG. 9 and FIG. 10 are cross sectional views of the termination region 1b of a semiconductor device according to the comparative example. In FIG. 9 and FIG. 10, components similar to those of the above-described semiconductor device 1 are labeled with the same reference signs and a redundant description thereof is omitted.

No stopper film 16 is located in the termination region 1b of the semiconductor device according to the comparative example as illustrated in FIG. 9 and FIG. 10. This causes an end portion of the protection film 15 to be in a tapered shape. For example, a taper angle of the end portion of the protection film 15 is small in FIG. 9, which makes the protection film 15 likely to stretch from the termination region 1b to the second dicing line L2. Accordingly, in order to secure the coverage the metal wiring line 14, it is necessary to design a dicing line width W1 to be relatively wide.

Meanwhile, a tapered shape of the end portion of the protection film 15 illustrated in FIG. 10 is different from the tapered shape of the end portion of the protection film 15 illustrated in FIG. 9. As a result, a dicing line width W2 illustrated in FIG. 10 is longer than the dicing line width W1 illustrated in FIG. 9. As seen from the above, impairment of the uniformity of the shape of the end portion of the protection film 15 makes the dicing line width likely to vary.

Contrastively, the stopper film 16 is formed before the protection film 15 in the present embodiment as described above. The end portion of the protection film 15 thus comes into contact with the side surface stopper film 16, being blocked from moving toward the second dicing line L2. This makes it possible to fix the dicing line width W at the distance between the stopper films 16. In other words, a dimension of the dicing line width W is controllable in accordance with the distance between the stopper films 16. Therefore, it is possible to narrow the dicing line width W and improve a variation in dicing line width.

### Second Embodiment

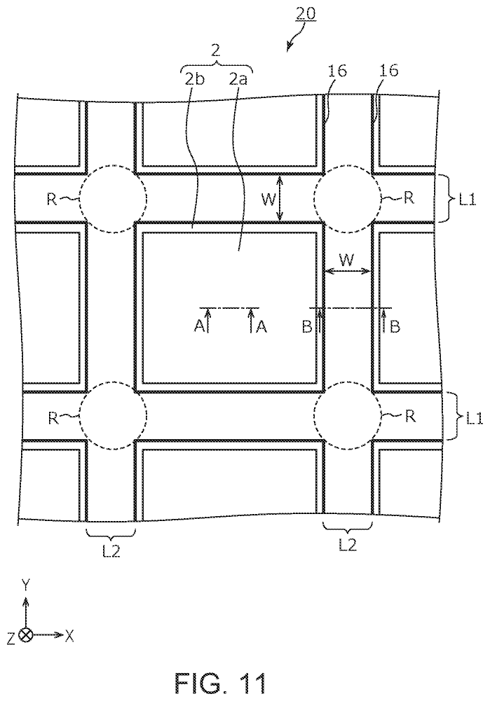

FIG. 11 is a plan view of a semiconductor device according to a second embodiment. A semiconductor device 2 illustrated in FIG. 11 is in a state of not being diced from a semiconductor wafer 20. In FIG. 11, components similar to those of the semiconductor device 1 according to the above-described first embodiment are labeled with the same reference signs.

The semiconductor device 2 according to the present embodiment includes a cell region 2a and a termination region 2b. A structure of the cell region 2a is similar to the structure of the cell region 1a according to the first embodiment and a description thereof is omitted, accordingly.

Additionally, the termination region 2b has a structure similar to that of the termination region 1b according to the first embodiment. Further, the termination region 2b can be formed through steps similar to those of the manufacturing method of the termination region 1b described in the first embodiment. Incidentally, in the present embodiment, a planar shape of the stopper film 16 formed in the semiconductor wafer 20 is different from in the semiconductor device 1 according to the first embodiment.

In the semiconductor device 1 according to the first embodiment, the stopper film 16 extends not only in an outer peripheral portion of the termination region 1b but also in an intersection region R between the first dicing line L1 and the second dicing line L2 as illustrated in FIG. 1. Thus, within the intersection region R, a portion provided with the stopper film 16 is in a form of a projecting portion and a portion provided with no stopper film 16 is in a form of a recessed portion. This necessitates dicing of the projecting and recessed portions in dicing the semiconductor wafer 10 along the first dicing lines L1 and the second dicing lines L2 using a blade.

In contrast, in the semiconductor device 2 according to the present embodiment, the stopper film 16 ends at the termination region 1b and does not extend to the intersection region R as illustrated in FIG. 11. In other words, no stopper film 16 is located in the intersection region R. Thus, the intersection region R has neither a projecting portion nor a recessed portion. This causes a flat portion in the intersection region R to be diced in dicing the semiconductor wafer 20 along the first dicing lines L1 and the second dicing lines L2 using a blade.

According to the above-described present embodiment, the stopper film 16 is formed in the termination region 2b before the protection film 15 as in the first embodiment. The end portion of the protection film 15 thus comes into contact with the side surface stopper film 16, being blocked from moving toward the second dicing line L2. This makes it possible to fix the dicing line width W at the distance between the stopper films 16. Therefore, it is possible to narrow the dicing line width W and improve a variation in dicing line width.

Additionally, in the present embodiment, the dicing in the intersection region R is flat dicing. This allows the semiconductor wafer 20 to be diced more smoothly than in the first embodiment.

It should be noted that although remaining as one component of the semiconductor devicees 1, 2 in the first embodiment and the second embodiment, the stopper film 16 may be removed before the dicing step or after the dicing step. This is because the removal of the stopper film 16 has no influence on electric properties of the semiconductor devicees 1, 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The invention claimed is:

1. A manufacturing method of a semiconductor device, the semiconductor device being located on a semiconductor wafer within a region surrounded by a first dicing line extending in a first direction and a second dicing line perpendicular to the first direction, the semiconductor device including a cell region and a termination region, the cell region including a semiconductor device located within a semiconductor substrate, the termination region including a metal wiring line located on the semiconductor substrate and electrically connected to the semiconductor device, the method comprising:
forming a stopper film around the metal wiring line in the termination region;
forming a protection film, the protection film covering the metal wiring line and ending at a side surface of the stopper film; and
dicing the semiconductor wafer along the first dicing line and the second dicing line.

2. The manufacturing method according to claim 1, wherein the stopper film includes an oxide film, a nitride film, or an electrically conductive film.

3. The manufacturing method according to claim 1, wherein a height of the stopper film is greater than a thickness of the metal wiring line.

4. The manufacturing method according to claim 2, further comprising:
covering the metal wiring line and an upper surface of the semiconductor substrate with the oxide film, the nitride film, or the electrically conductive film;
applying a photoresist to, within the oxide film, the nitride film, or the electrically conductive film, a portion that is to be left as the stopper film;
etching the oxide film, the nitride film, or the electrically conductive film using the photoresist as a mask; and
removing the photoresist.

5. The manufacturing method according to claim 1, wherein the stopper film extends in an intersection region between the first dicing line and the second dicing line.

6. The manufacturing method according to claim 1, wherein the stopper film ends at the termination region and does not extend in an intersection region R between the first dicing line and the second dicing line.

7. The manufacturing method according to claim 1, wherein the protection film includes a polyimide film.

8. The manufacturing method according to claim 1, wherein the semiconductor device includes an IGBT (Insulated Gate Bipolar Transistor) or a MOSFET (Metal Oxide Semiconductor Field Effect Transistor).

9. A semiconductor device comprising:
a cell region including a semiconductor device; and
a termination region surrounding the cell region,
wherein the termination region includes:
a metal wiring line electrically connected to the semiconductor device;
a protection film covering the metal wiring line; and
a stopper film having a side surface being in contact with an end portion of the protection film.

10. The semiconductor device according to claim 9, wherein the stopper film includes an oxide film, a nitride film, or an electrically conductive film.

11. The semiconductor device according to claim 9, wherein a height of the stopper film is greater than a thickness of the metal wiring line.

12. The semiconductor device according to claim 9, wherein the protection film includes a polyimide film.

13. The semiconductor device according to claim 9, wherein the semiconductor device includes an IGBT or a MOSFET.
